(19) United States
(12) Patent Application Publication
(10) Pub. No.: US 2023/0260588 A1
(43) Pub. Date: Aug. 17, 2023

(54) SYSTEMS AND METHODS FOR SENSE CIRCUIT TESTING BY SENSOR EMULATION IN MEMORY DIE

(71) Applicant: SanDisk Technologies LLC, Addison, TX (US)

(72) Inventors: Ella Wu, Shanghai (CN); Ruru Ji, Shanghai (CN); Janice Zhang, Shanghai (CN); Howard Qiu, Shanghai (CN)

(21) Appl. No.: 17/670,720

(22) Filed: Feb. 14, 2022

(51) Int. Cl. G11C 29/12; G11C 7/04; G11C 7/16; H03M 1/46

(52) U.S. Cl. CPC G11C 29/1201; G11C 29/12005; G11C 7/04; G11C 7/16; H03M 1/462

(57) ABSTRACT

Systems and methods are provided for environmental testing of memory devices without altering the physical environment. One or more voltage source(s) of the memory die can be used as additional test mode inputs as test analogues for environmental sensor signals, such as voltage proportional signals. This can improve environmental circuit testability (e.g., cost, performance, speed, up-time) inasmuch as target circuitry can be used in an automatic way to reduce or prevent production failures. Target circuitry can be exercised in an on-the-fly manner to enable rapid, frequent testing, including in the field, with little memory system down-time.

### DESCRIPTION OF RELATED ART

Semiconductor memory is widely used in various electronic devices such as cellular telephones, digital cameras, personal digital assistants, medical electronics, mobile computing devices, and non-mobile computing devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory) and Electrically Erasable Programmable Read-Only Memory (EEPROM). Sensor circuits, such as temperature sensor circuits, can be used as peripheral circuits for non-volatile memory, where bias levels of the non-volatile memory vary based upon variations in the environment, such as temperature. With respect to testing non-volatile memory, (e.g., during manufacturing), elements of one or more memory devices can be tested at various environmental conditions, such as varying temperatures set by an oven.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1A illustrates a block diagram of a memory system used to implement various features of embodiments described in the present disclosure.

FIG. 1B illustrates example components of a memory die of the memory system of FIG. 1A in more detail, which can be used to implement various features of embodiments described in the present disclosure.

FIG. 1C illustrates a block diagram depicting one example of a memory structure, which can be used to implement various features of embodiments described in the present disclosure.

FIG. 2A shows an example configuration of an example environmental sense circuitry of the memory die, which can be used to implement various features of embodiments described in the present disclosure.

FIG. 2B is a block diagram of another example environmental sense circuitry, which can be used to implement various features of embodiments described in the present disclosure.

FIG. 2C is a block diagram of another example environmental sense circuitry, which can be used to implement various features of embodiments described in the present disclosure.

FIG. 2D is block diagram of example temperature sense circuitry, which can be used to implement various features of embodiments described in the present disclosure.

FIG. 3 shows an example signal from a voltage proportional signal generator that can be used to implement various features of embodiments described in the present disclosure.

FIG. 4 shows example control signals generated for voltage proportional signal based sense circuits described herein, and respective coded outputs, in accordance with various embodiments of the present disclosure.

FIG. 5 shows possible combinations for a four-bit successive approximation register (SAR) analog to digital converter (ADC), which can be used to implement various features of embodiments described in the present disclosure.

FIG. 6A shows example steps of a method that can be performed for the implementation of various features of embodiments described in the present disclosure.

FIG. 6B shows example steps of another method that can be performed for the implementation of various features of embodiments described in the present disclosure.

The figures are not exhaustive and do not limit the present disclosure to the precise form disclosed.

### DETAILED DESCRIPTION

The memory cells of memory cards have, in recent years, been designed to store more than one level. Consequently, each memory cell can store a signal that represents one of a plurality of digital values. For example, a single memory cell might store one of eight (e.g., in triple-level cell flash (TLC), or one of sixteen voltage levels (quad-level cell (QLC) flash). The ability for individual memory cells (for example, the TLC, QLC, or other multi-level cells (MLCs)) to store multiple levels allows the storage density of memory cards to be greatly improved. However, the amount of voltage being stored to read from memory cells can vary with the ambient and/or local environment. As more and more data states are being stored within a smaller range of voltage levels, the accuracy of reading of stored data will be improved if environmental variations such as temperature variations, are considered during sensing. As such, with respects to the environment of the memory cell, it may be useful to sense one or more aspects of the ambient and/or local environment. With respect to temperature, for example, temperature compensated voltages are utilized for more accurately reading signals (e.g., voltages) representing data stored in memory cells of a memory system.

One example temperature-compensated voltage is a voltage proportional signal that is proportional to absolute temperature, which can be useful in band gap reference voltage generation. A signal generator can sense the temperature (i.e., of one or more memory cells and/or of the memory die) and generate an analog signal which is proportional to absolute temperature. With respect to temperature, the bias voltage generated by a temperature compensated bias voltage generator (or voltage generation circuit described herein) can be based on the operating temperature of the flash memory. In an analog to digital converter (ADC), the voltage proportional signal can be compared to a temperature-independent reference voltage to produce a digital output (temperature code) at respective temperatures. The number of temperature code outputs can depend on the bits of the ADC.

With respect to testing (e.g., at the factory or during manufacturing), one or more environmental parameters can be cycled. For example, with respect to temperature, elements of one or more memory devices can be tested at various temperatures. One or more environmental conditions varying systems can be used to vary environmental conditions of the die, such as to one or more set-points. For example, a vacuum chamber can be used to vary the pressure between pressure set points. As another example, one or more ovens or refrigeration devices can be used to vary the temperature to various temperature set points. For example, an oven can raster through various temperature set-points to test various elements of the memory die. Aspects of the present disclosure enable improvements to memory device environmental testing and environmental circuit testing without varying various physical environmental conditions of the memory devices.

As previously discussed, aspects of the present disclosure enable environmental testing of memory devices without altering the physical environment. As such, aspects of the present disclosure enable improvement(s) to the testability of memory devices, increasing the speed and practicability of memory device testing. As previously alluded to, as storage capacity/density of memory device(s) improve, memory devices may be more sensitive to environmental changes. As such, improvements to memory device environmental circuit testing, which aspects of the present disclosure enable, are increasingly important. The present disclosure includes using one or more voltage source(s) of the memory die as additional test mode inputs as test analogues for environmental sensor signals, such as voltage proportional signals. This can improve environmental circuit testability (e.g., cost, performance, speed, up-time). Methods and systems disclosed herein enable exercising target circuitry in an automatic way to reduce or prevent production failures. Methods and systems disclosed herein enable exercising target circuitry in an on-the-fly manner to enable rapid, frequent testing, including in the field, with little memory system down-time.

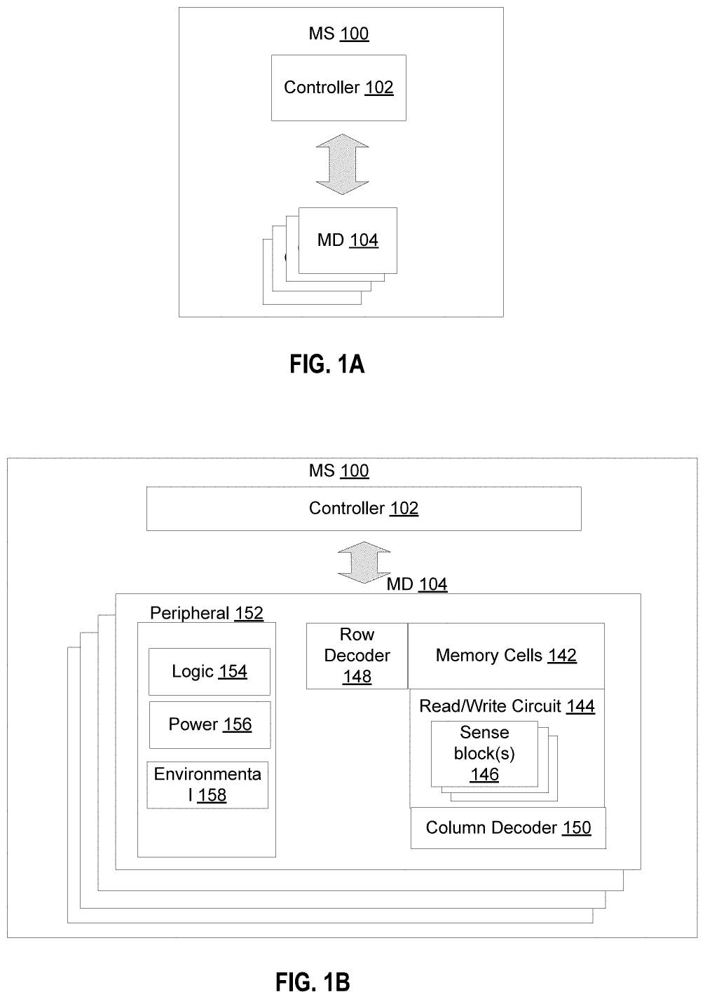

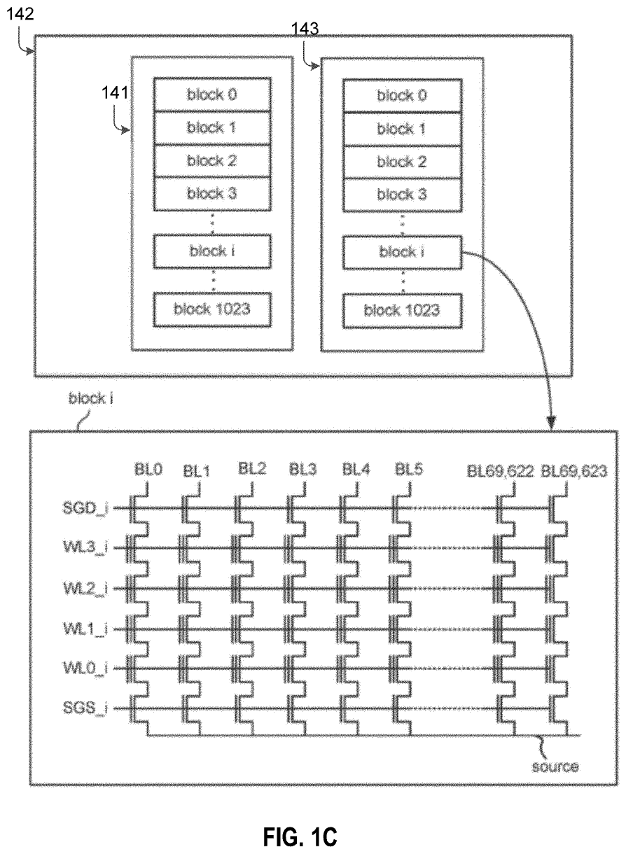

FIG. 1A is a block diagram illustrating a memory system 100. The memory system 100 may include a controller 102 and memory that may be made up of one or more non-volatile memory dies 104 (referred to collectively as memory dies 104). As used herein, the term die refers to the set of memory cells, and associated circuitry for managing the physical operation of those memory cells, that are formed on a single semiconductor substrate. The controller 102 may interface with a host system and transmit command sequences for read, program, and erase operations to the memory dies 104. The interface may include a bus or other communication mechanism for communicating information.

The controller 102 (which may be a flash memory controller) can take the form of a processing circuitry, a microprocessor or processor, or a computer-readable medium that stores computer-readable program code (e.g., software or firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Components may store internal or external to the controller. Additionally, the phrase “operatively in communication with” could mean directly in communication with or indirectly (wired or wireless) in communication with through one or more components, which may or may not be shown or described herein.

As used herein, the controller 102 is a device that manages data stored in the memory dies 104 and communicates with a host, such as a computer or electronic device. The controller 102 can have various functionality in addition to the specific functionality described herein. For example, the controller 102 can format the memory dies 104 to ensure that they are operating properly, map out bad flash memory cells, and allocate spare cells to be substituted for future failed cells. Some part of the spare cells can be used to hold firmware to operate the controller 102 and implement other features. In operation, when a host needs to read data from or write data to the memory dies 104, the host will communicate with the controller 102. If the host provides a logical address to which data is to be read/written, the controller 102 can convert the logical address received from the host to a physical address in the memory dies 104. Alternatively, the host can provide the physical address. The controller 102 can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between the controller 102 and the memory dies 104 may be any suitable interface, such as flash interface. For some example embodiments, the memory system 100 may be a card based system, such as a secure digital (SD) or a micro secure digital (micro-SD) card. In alternate example embodiments, the memory system 100 may be part of an embedded memory system.

The controller 102 may include a front-end module that interfaces with a host, a back-end module that interfaces with the memory dies 104, and various other modules that perform various functions of the memory system 100. In general, a module may be hardware or a combination of hardware and software. Module may include one or more electronic circuits that include electronic components for performing the functionality of one or more instructions. For example, each module may include an application specific integrated circuit (ASIC), a field programmable gate array (FPGA), a circuit, a digital logic circuit, an analog circuit, a combination of discrete circuits, gates, or any other type of hardware or combination thereof. In addition, or alternatively, each module may include memory hardware that comprises instructions executable with a processor or processor circuitry to implement one or more of the features of the module. When any one of the modules includes the portion of the memory that comprises instructions executable with the processor, the module may or may not include the processor. In some examples, each module may just be the portion of the memory that comprises instructions executable with the processor to implement the features of the corresponding module without the module including any other hardware. Because each module includes at least some hardware even when the included hardware comprises software, each module may be interchangeably referred to as a hardware module. Each module may include one or more instructions for execution of logic of one or more circuits described herein. In embodiments, processor 102 may fetch, decode, and/or execute one or more instructions to control processes and/or operations for enabling aspects of the present disclosure.

In general, the word “component,” “module,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression, or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

In the example illustrated in FIG. 1A, the memory system 100 is shown including a single channel between the controller 102 and the memory dies 104. However, the subject matter described herein is not limited to such single channel memory systems. For example, in some memory systems, such as those embodying NAND architectures, 2, 4, 8 or more channels may exist between the controller 102 and the memory dies 104, depending on controller capabilities. In any of the embodiments described herein, more than a single channel may exist between the controller 102 and the memory dies 104, even if a single channel is shown in the drawings.

FIG. 1B is a block diagram illustrating exemplary components of a memory die 104 of the memory system 100 of FIG. 1A in more detail. The memory die 104 may include a memory cell structure 142 (such as an array, and so forth) that includes a plurality of memory cells or memory elements. Any suitable type of memory can be used for the memory cells of the memory cell structure 142. As examples, the memory can be dynamic random access memory (“DRAM”) or static random access memory (“SRAM”), non-volatile memory, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory may have different configurations. For example, flash memory devices may be configured in a NAND or a NOR configuration.

The memory can be formed from passive and/or active elements, in any combinations. Byway of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

A person of ordinary skill in the art will recognize that the technology described herein is not limited to a single specific memory structure, but covers many relevant memory structures within the spirit and scope of the technology as described herein and as understood by one of ordinary skill in the art.

Multiple memory elements may be configured so that they are connected in series or so that each element is individually accessible. By way of non-limiting example, flash memory devices in a NAND configuration (NAND memory) typically contain memory elements connected in series. The memory cell structure 142 can include a NAND memory array. The NAND memory array may be configured so that the array is composed of multiple strings of memory in which a string is composed of multiple memory elements sharing a single bit line and accessed as a group.

NAND strings can include multiple transistors in series between a first select gate (i.e., a drain-side select gate) and a second select gate (i.e., a source-side select gate). A first select gate can connect the NAND string to a bit line. The second select gate can connect the NAND string to a source line. Each of the transistors in the NAND string can include a control gate and a floating gate. Control gates of respective transistors can be connected to word lines, respectively. Although four floating-gate transistors are described with reference to a NAND string, the use of four floating-gate transistors is only provided as an example. A NAND string may have less than or more than four floating-gate transistors (or memory cells). For example, some NAND strings may include 16 memory cells, 32 memory cells, 64 memory cells, 128 memory cells, etc. The discussion herein is not limited to any particular number of memory cells in a NAND string. One embodiment uses NAND strings with 66 memory cells, where 64 memory cells are used to store data and two of the memory cells are referred to as dummy memory cells because they do not store data.

A typical architecture for a flash memory system using a NAND flash memory structure includes a plurality of NAND strings within a memory block. In some cases, the NAND strings within a memory block may share a common well (e.g., a P-well). Each NAND string may be connected to a common source line by its source-side select gate (e.g., controlled by select line) and connected to its associated bit line by its drain-side select gate (e.g., controlled by select line). Typically, each bit line runs on top of (or over) its associated NAND string in a direction perpendicular to the word lines and is connected to a sense amplifier.

Alternatively to a NAND memory array, memory elements may be configured so that each element is individually accessible, e.g., a NOR memory array. NAND and NOR memory configurations are exemplary, and memory elements may be otherwise configured. Although technology using NAND-type flash memory may be described herein, the technology disclosed herein may also be applied to other types of non-volatile storage devices and architectures (e.g., NOR-type flash memory). Moreover, although technology using floating-gate transistors is described herein, the technology described herein may also be applied to or used with other memory technologies including those that employ charge trapping, phase-change (e.g., chalcogenide materials), or state-change materials.

The semiconductor memory elements located within and/or over a substrate of memory die 104 may be arranged in two or three dimensions, such as a two dimensional or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular, and the x and z directions are substantially parallel to the major surface of the substrate).

As previously alluded to, in one embodiment, the array of the memory cell structure 142 may be divided into a large number of blocks (e.g., blocks 0-1023, or another amount) of memory cells. A block contains a set of NAND strings which are accessed via bit lines and word lines. Typically, all the NAND strings in a block share a common set of word lines.

Each block may be divided into a particular number of pages. In one embodiment, a page may be the unit of programming. Other units of programming can also be used. One or more pages of data are typically stored in one row of memory cells. For example, one or more pages of data may be stored in memory cells connected to a common word line. In one embodiment, the set of memory cells that are connected to a common word line are programmed simultaneously. A page can store one or more sectors. A sector may include user data and overhead data (also called system data). Overhead data typically includes header information and Error Correction Codes (ECC) that have been calculated from the user data of the sector. The controller (or other component) calculates the ECC when data is being programmed into the array and checks it when data is being read from the array. Alternatively, the ECC and/or other overhead data may be stored in different pages, or even different blocks, than the user data to which they pertain. A sector of user data is typically 512 bytes, corresponding to the size of a sector in magnetic disk drives. A large number of pages form a block, anywhere from 8 pages, for example, up to 32, 64, 128 or more pages. Different sized blocks, pages, and sectors can also be used.

As shown in FIG. 1B, the memory die 104 may further include read/write circuits 144 that includes a plurality or p-number of sense blocks (also referred to as sense modules or sense circuits) 146. As described in further detail below, the sense blocks 146 can be configured to participate in reading or programming a page of memory cells in parallel.

The memory die 104 may also include a row address decoder 148 and a column address decoder 150. The row address decoder 148 may decode a row address and select a particular word line in the array of the memory cell structure 142 when reading or writing data to/from the memory cells 142. The column address decoder 150 may decode a column address to select a particular group of bit lines in the array of the memory cell structure 142 to read/write circuits 144.

In addition, the non-volatile memory die 104 may include peripheral circuitry 152. Although single peripheral circuitry 152 is shown, it can be understood that multiple peripheral circuitry 152, and/or modules, blocks or circuits that make up peripheral circuitry 152 can be included, and that functionality can be shared among the various modules or circuits. The peripheral circuitry 152 may include control logic circuitry 154, which may be implemented as a state machine, that provides on-chip control of memory operations as well as status information to the controller 102. The peripheral circuitry 152 may also include an on-chip address decoder (not shown) that provides an address interface between addressing used by the controller 102 and/or a host and the hardware addressing used by the row and column decoders 148, 150. In addition, the peripheral circuitry 152 may also include volatile memory (not shown). An example configuration of the volatile memory may include latches, although other configurations are possible.

In addition, the peripheral circuitry 152 may include power control circuitry 156 that is configured to generate and supply voltages to the array of the memory cell structure 142, including voltages (including program voltage pulses) to the word lines, erase voltages (including erase voltage pulses), the source select gate bias voltage to the source select gate bias line, the drain select gate bias voltage to the drain select gate bias line, a cell source voltage on the source lines, as well as other voltages that may be supplied to the array of the memory cell structure 142, the read/write circuits 144, including the sense blocks 146, and/or other circuit components on the memory die 104 such as peripheral circuit 152. The various voltages that are supplied by the power control circuitry 156 are described in further detail below. The power control circuitry 156 may include any of various circuit topologies or configurations to supply the voltages at appropriate levels to perform the read, write, and erase operations, such as driver circuits, charge pumps, reference voltage generators, and pulse generation circuits, or a combination thereof. Other types of circuits to generate the voltages may be possible. In addition, the power control circuitry 156 may communicate with and/or be controlled by the control logic circuitry 154, the read/write circuits 144, and/or the sense blocks 146 to supply the voltages at appropriate levels and appropriate times to carry out the memory operations.

To program a target memory cell, and in particular a floating gate transistor (FGT), the power control circuitry 156 can apply a program voltage to the control gate of the memory cell, and the bit line that is connected to the target memory cell is grounded, which in turn causes electrons from the channel to be injected into the floating gate. As previously described, in a block, one memory cell in each of the NAND strings can share the same word line.

As previously described, the threshold voltage VTH of a memory cell may identify the data value of the data it is storing. For a given read operation in a block, a memory cell from which data is to be read is referred to as a selected memory cell, and a memory cell from which data is not to be read is referred to as an unselected memory cell. So, when data is to be read from a page of memory cells for a particular read operation, those memory cells in the page are the selected memory cells, and the memory cells of the block that are not part of the page are the unselected memory cells. Additionally, a word line connected to the page of selected memory cells is referred to as the selected word line, and the other word lines of the block are referred to as the unselected word lines.

During a read operation to read data stored in target memory cells of a page, the sense blocks 146 may be configured to perform a sense operation that senses whether current is flowing through the bit lines connected to the target memory cells of the page. Voltage supply circuitry (described with reference to peripheral circuitry 152 in FIG. 1B) may supply voltages on the selected and unselected word lines at appropriate levels that cause current to flow or not to flow based on the threshold voltage of the target memory cells. For some configurations, the level of the voltage supplied to the selected word lines may vary depending on the states of the memory cells.

A power control circuit 156 can generate a one or more voltages necessary for voltage proportional signal generation as described herein. The power control circuit 156 may be configured to generate a bias voltage generated by a temperature compensated bias voltage generation generator or circuit as described herein. A bias voltage can be based on the operating temperature of the flash memory and can be temperature compensated as described herein. The power control circuit 156 can be configured to generate a band gap reference voltage. The power control circuitry 156 can include voltage supply circuitry and/or other circuitry configured to generate one or more voltages described herein. For example, the voltage supply circuitry (described with reference to the power control circuitry 156) may bias the bit lines so that the high supply voltage is applied to the drain side of the bit lines and the cell source voltage is applied to the source side of the bit lines to allow for the current flow, provided that the threshold voltage of the selected memory cell allows for it. For some example read configurations, the sense block 146 can perform a sense operation for fewer than all the memory cells of a page. For such configurations, the target memory cells of the page that are subject to and/or that are selected for a given sense operation are referred to as selected memory cells or selected target memory cells. Conversely, the target memory cells of the page that are not subject to and/or that are not selected for the sense operation are referred to as unselected memory cells. Accordingly, bit lines connected to selected target memory cells are referred to as selected bit lines, and bit lines connected to unselected target memory cells are referred to as unselected bit lines. In this context, a state of the bit line may refer to whether the bit line is selected or unselected. Otherwise stated, a bit line can be in one of two states, selected or unselected. The voltage supply circuitry (described with respect to the power control circuitry 156) can supply the voltages to the selected and unselected word lines and the selected and unselected bit lines at levels in various combinations, in various sequences, and/or over various sense operations to determine the threshold voltages of the target memory cells so that the data values of the data that the target memory cells are storing can be determined.

As previously alluded to, sensing (e.g., reading) of memory cells of the memory cell structure 142 can be affected by one or more environmental parameters. Although aspects of the present disclosure may focus on temperature, it can be understood that the present disclosure applies to other environmental parameters such as humidity, acceleration, pressure, E/M radiation, etc. The peripheral circuitry 152 may include an environmental parameter sense circuitry 158, such as temperature sense circuitry. The environmental parameter sense circuitry 158 can interface with the power control circuit 156, for example, with respect to temperature sense circuitry, to generate a voltage proportional signal described herein. As another example, one or more signals can be generated for the environmental parameter sense circuitry 158. The environmental parameter sense circuitry 158 can interface with the power control circuit 156, for example, to generate one or more bias voltages described herein. The environmental parameter sense circuitry 158 can include one or more environmental parameter sensors, and (alone or in combination with the power control circuit 156) generate an analog signal which is related to a value of the environmental parameter. For example, the analog signal can be proportional to absolute humidity, acceleration, pressure, and/or temperature. It can be understood that the analog signal generated by the environmental parameter sense circuitry 158 can generate one or more of a charge, voltage, current, amplitude, frequency, pulse-width, which is related to a value of the environmental parameter. It can also be understood that the environmental parameter sense circuitry 158 can generate a digital output, such as a hexadecimal, decimal, binary, and/or a coded signal based on the value of the environmental parameter.

FIG. 1C depicts a block diagram of an example of memory cell structure 142. In one embodiment, an array of memory cells is divided into multiple planes. In the example of FIG. 1C, the memory cell structure 142 is divided into two planes: plane 141 and plane 143. In other embodiments, more or less than two planes can be used. In some embodiments, each plane is divided into a number of memory erase blocks (e.g., blocks 0-1023, or another amount). In certain memory technologies (e.g., 2D/3D NAND and other types of flash memory), a memory erase block is the smallest unit of memory cells for an erase operation. That is, each erase block contains the minimum number of memory cells that are erased together in a single erase operation. Other units of erase can also be used. In other memory technologies (e.g., MRAM, PCM, etc.) used in other embodiments implementing the solution claimed herein, memory cells may be overwritten without an erase operation and so erase blocks may not exist.

Each memory erase block includes many memory cells. The design, size, and organization of a memory erase block depends on the architecture and design for the memory cell structure 142. As used herein, a memory erase block is a contiguous set of memory cells that share word lines and bit lines; for example, erase block i of FIG. 1C includes memory cells that share word lines WL0_i, WL1_i, WL2_i and WL3_i and share bit lines BL0-BL69,623.

In one embodiment, a memory erase block (see block i) contains a set of NAND strings which are accessed via bit lines (e.g., bit lines BL0-BL69,623) and word lines (WL0, WL1, WL2, WL3). FIG. 1C shows four memory cells connected in series to form a NAND string. Although four cells are depicted to be included in each NAND string, more or less than four can be used (e.g., 16, 32, 64, 128, 256 or another number or memory cells can be on a NAND string). One terminal of the NAND string is connected to a corresponding bit line via a drain select gate, and another terminal is connected to the source line via a source select gate. Although FIG. 1C shows 69,624 bit lines, a different number of bit lines can also be used.

Each memory erase block and/or each memory storage unit is typically divided into a number of pages. In one embodiment, a page is a unit of programming/writing and a unit of reading. Other units of programming can also be used. One or more pages of data are typically stored in one row of memory cells. For example, one or more pages of data may be stored in memory cells connected to a common word line. A page includes user data and overhead data (also called system data). Overhead data typically includes header information and ECC that have been calculated from the user data of the sector. The controller (or other component) calculates the ECC when data is being written into the array, and also checks it when data is being read from the array. In one embodiment, a page includes data stored in all memory cells connected to a common word line.

In the example discussed above, the unit of erase is a memory erase block and the unit of programming and reading is a page. Other units of operation can also be used. Data can be stored/written/programmed, read, or erased a byte at a time, 1K bytes, 512K bytes, etc. No particular unit of operation is required for the claimed solutions described herein. In some examples, the system programs, erases, and reads at the same unit of operation. In other embodiments, the system programs, erases, and reads at different units of operation. In some examples, the system programs/writes and erases, while in other examples the system only needs to program/write, without the need to erase, because the system can program/write zeros and ones (or other data values) and can thus overwrite previously stored information.

As used herein, a memory storage unit is the set of memory cells representing the smallest storage unit of operation for the memory technology to store/write/program data into the memory cell structure 142. For example, in one embodiment, the memory storage unit is a page sized to hold 4 KB of data. In certain embodiments, a complete memory storage unit is sized to match the number of physical memory cells across a row of the memory cell structure 142. In one embodiment, an incomplete memory storage unit has fewer physical memory cells than a complete memory storage unit.

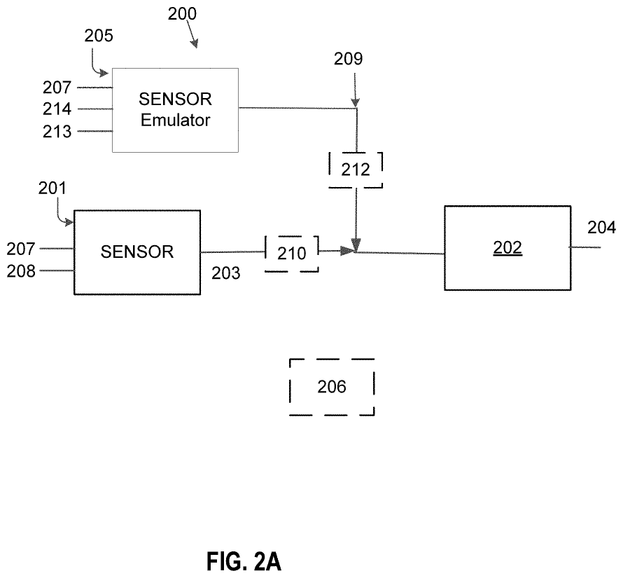

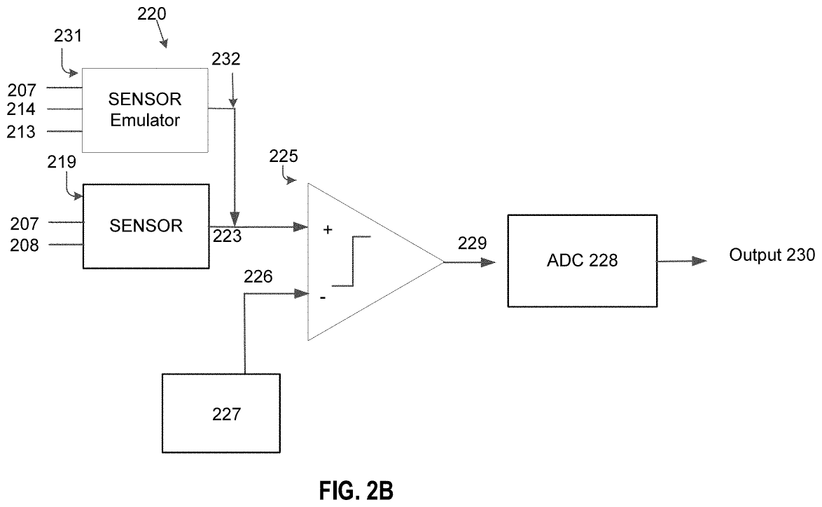

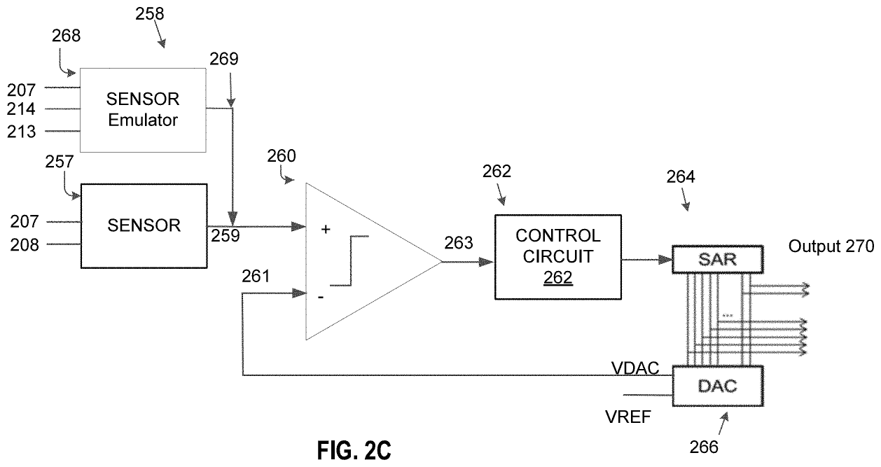

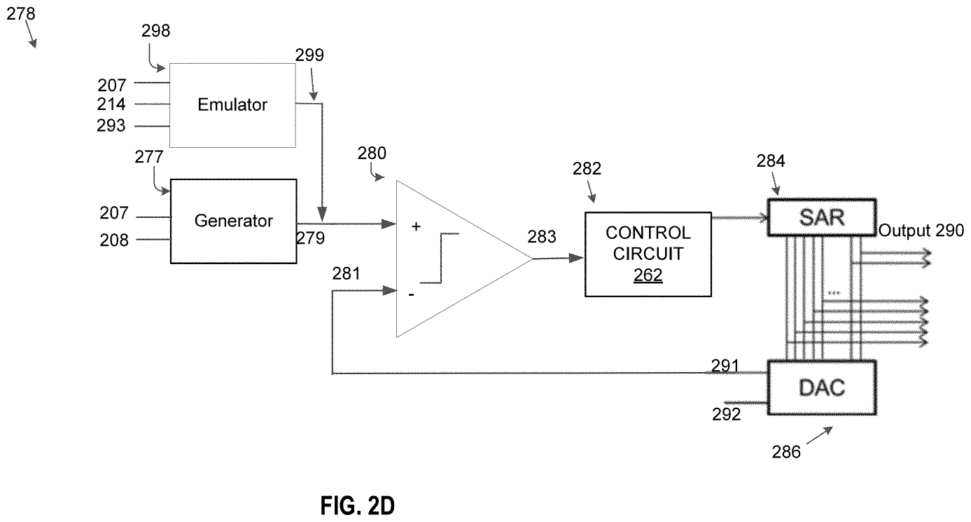

FIG. 2A is a block diagram of an example environmental sense circuitry 200, which may be representative of the environmental sense circuitry 158 of FIG. 1B. Environmental sense circuitry 200 can include a sensor 201, and other circuitry 202, which can be configured, for example, to transform a signal 203 from the sensor 201 into an output 204. As such, the other circuitry 202 can generally be output circuitry for generating an output. The signal 203 from the sensor 201 can be based on one or more sensed environmental parameters, such as temperature, humidity, etc. For example, a charge, voltage, current, amplitude, frequency, and/or pulse-width level can be based on a value for the one or more sensed environmental parameter. The other circuitry 202 can depend on the type of signal 203 generated by the sensor 201.

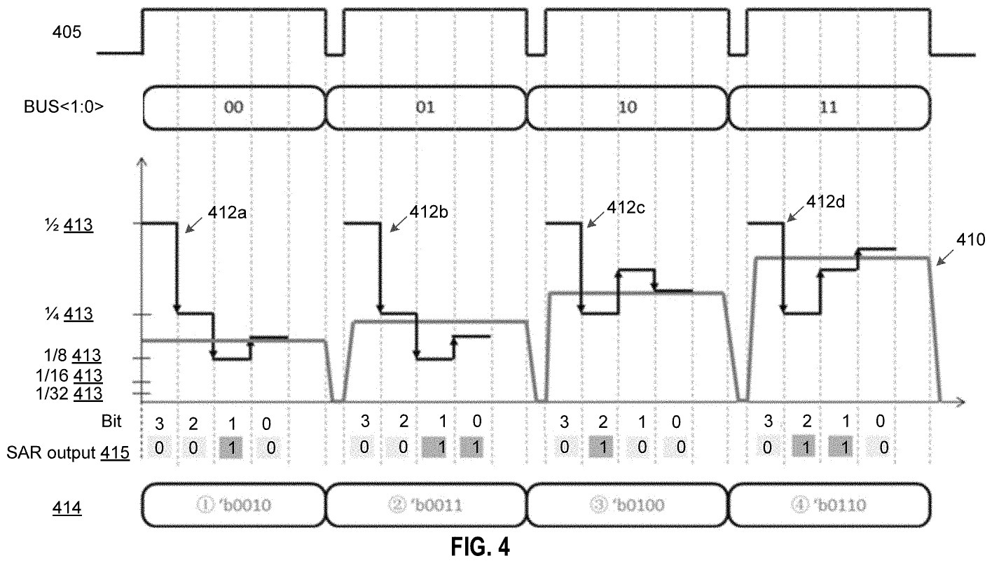

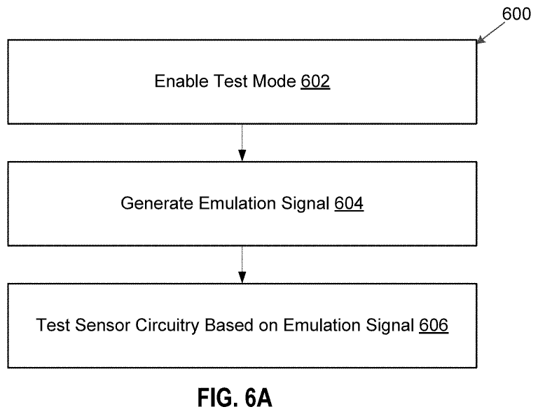

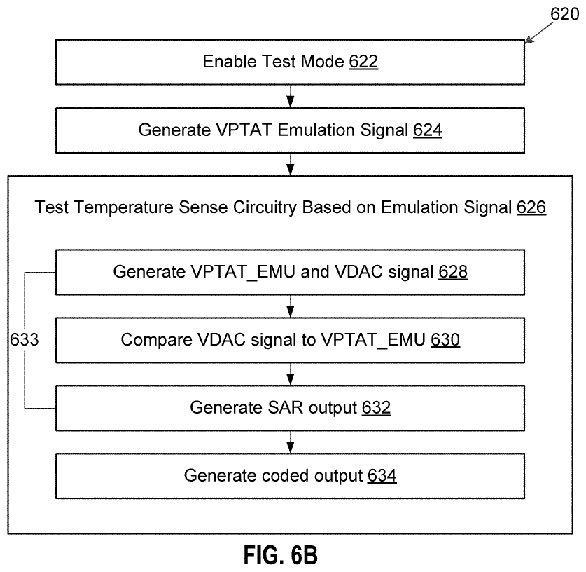

Additionally, the environmental sense circuitry 200 may include an environmental sensing controller 206 that is configured to control operation of the environmental sense circuitry 200. As described in further detail below, the environmental sensing controller 206 may control aspects of the environmental sense circuitry 200 by outputting control signals to terminals of the various components of the environmental sense circuitry 200. Additionally, the environmental sensing controller 206 may communicate with and/or may be a part of the control logic circuit 154 or other controller of peripheral device 152 (with reference to FIG. 1B). The environmental sensing controller 206 may be implemented in hardware, or a combination of hardware and software. For example, the environmental sensing controller 206 may include a processor that executes computer instructions stored in memory to perform at least some of its functions. The environmental sensing controller 206 can be configured with various modules to perform one or more functions. In embodiments, the environmental sensing controller 206 may fetch, decode, and/or execute one or more instructions to control processes and/or operations for enabling aspects of the present disclosure. For example, instructions can be for generating one or more signals shown in FIG. 4 (below) or sensing one or more voltage levels. Instructions can include instructions for executing steps shown in the methods 600 and 620 of FIG. 6A and FIG. 6B (below). The environmental sensing controller 206 can send messages and receive data, including program code, through one or more communication interfaces. The received code may be executed by processor of the environmental sensing controller 206 as it is received, and/or stored in storage device or other non-volatile storage for later execution.

The environmental sense circuitry 200 can further include a sensor emulator 205, which is configured to generate an emulated signal 209. The sensor emulator 205 can enable improvement(s) to the testability of memory devices, increasing the speed and practicability of testing aspects of the environmental sense circuitry 200 and other elements of the memory system 100. In some embodiments, whereas a specific value for an environmental parameter, as sensed by the sensor 201, can allow for generation of a first level of the signal 203 from sensor 201, the sensor emulator 205 can be configured to generate the emulated signal 209 having a signal level with the same level of signal 203 from sensor 201, without having to sense a specific value (or set of values) for environmental parameter(s). For example, the sensor emulator 205 can generate the emulated signal 209 with similar charge, voltage, current, amplitude, frequency, and/or pulse-width level that could be generated by the sensor 203. During testing, the sensor emulator 205 can allow for testing aspects of the other circuitry 202, without the physical environment needing to be configured in a specific way (for example, by varying environmental conditions of the memory die 104). In addition, other elements of the memory system interface 100 with the environmental sense circuit 200. For example, various elements of the memory system 100 utilize the output 204. As such, other elements of the memory system 100 can be tested by way of the sensor emulator 205.

The sensor emulator 205 can be, be powered by, or include the power control circuitry 156 (which can include voltage supply circuitry) as described with reference to FIG. 1B. With respect to memory die 104, it may be useful to save die space and/or power to also use power control circuitry 156, e.g., the voltage supply circuitry as the sensor emulator 205. For example, the power control circuitry 156, in other operations, can be configured to generate signals that control other aspects of the memory die 104 (e.g., memory storage, and/or bias voltage generation).

In some embodiments, a power signal 207 can be generated by the power control circuitry 156 (e.g., voltage supply circuitry). The power control circuitry 156 or the environmental sensing controller 206 can interface with the sensor 201 and/or the sensor emulator 205 so that one or more signals (e.g., the power signal) can power one or more aspects of the environmental sense circuitry 200. The power signal 207 can include a sufficient voltage and/or current for powering the sensor 201 and/or the sensor emulator 205. The environmental sensing controller 206 (or another controller or circuit of the memory die 104), can be configured to generate one or more signals, such as an enable signal 208. For example, an emulation signal 213 can be configured to control one or more aspects of the sensor emulator 205. In embodiments, the emulated signal 209 is based on the emulation signal 213. As another example of signals that the environmental sensing controller 206 or another controller or circuit of the memory die 104 can generate is a test enable signal 214 that, when active (e.g., at a high level), can signify that the environmental sense circuitry 200 is being tested or that a test mode is active. The test enable signal 214 can be configured to activate one or more aspects of the sensor emulator 205, including generation of one or more emulated signals 209. In embodiments, when the test enable signal 214 is disactivated (or low), the sensor 201 can operate and generate one or more signals 203. Alternatively, or additionally, the sensor 201 can be controlled by a separate sensor control signal, such as the enable signal 208, configured to indicate a normal operating mode, contrasted with the test mode.

The environmental sense circuitry 200 can include one or more switching circuits 210 and/or 212. The switching circuit 210 can be configured to switch in (i.e., to couple) the sensor 201 to the rest of the environmental sense circuitry 200, such as the other circuitry 202. The switching circuit 212 can be configured to switch in (i.e., to couple) the sensor emulator 205 to the rest of the environmental circuitry 200, such as the other circuitry 202. The switching circuit 210 can be controlled by an enable signal. The switching circuit 212 can be enabled by one or more signals such as the test enable signal, the power signal, and/or the emulation signal. For example, if a power to the sensor emulator 205 is active, the switching circuit 212 can activate to couple the sensor emulator 205 to the rest of the environmental circuitry 200. Although shown separately, the switching circuit 212 can be part of the sensor emulator 205, the switching circuit 210 can be part of the sensor 201, and/or each or either of the switching circuit 210, 212 can be an aspect of the environmental sensing controller 206 or the other circuitry 202. It can be understood that one or more control signals (e.g., generated by the environmental sensing controller 206), can allow for switching between a normal mode for sensing by the sensor 201, and an emulation or testing mode for testing aspects of the other circuitry 202.

FIG. 2B is a block diagram of an example sensor 219 based environmental sense circuitry 220, which may be representative of the environmental sense circuitry 158, 200 of FIG. 1B and FIG. 2A, respectively. Compared to FIG. 1B and FIG. 2A, FIG. 2B shows an alternative configuration of the environmental sense circuitry 158, 200, including details of the other circuitry 202 shown in FIG. 2A. Like sensor 201 of FIG. 2A, the environmental sense circuitry 220 can include sensor 219, which can generate a signal 223 based on one or more sensed environmental parameters. The environmental sense circuitry 220 can include a comparator circuit 225 configured to generate a comparator output signal 229 based on the sensor 219 generated signal 223. A signal at the (−) input of the comparator circuit 225 can be compared to a signal at the (+) input of the comparator circuit 225. For example, the sensor 219 generated signal 223 at the (+) input can be compared with a comparison signal 226 (e.g., to determine if one is less than, equal to, or greater than the other). The comparison signal 226 can be generated by a comparison signal generation circuit 227. The comparison signal generation circuit 227 can be the power circuitry 156 (with reference to FIG. 1B) including voltage generation circuitry. In some examples, the comparison signal 226 can be a reference voltage and can be generated by a reference voltage generator. The reference voltage can be a temperature-independent reference voltage can differ or change. Based on the comparison of the comparison signal 226 and the sensor 219 generated signal 223, the comparator output signal 229 can be generated by the comparator circuit 225.

It can be understood that the type of comparator circuit 225 is merely a non-limiting example. For example, if the sensor 219 is configured to generate varying current levels, the comparator circuit 225 can comprise a CMOS comparator to compare a current from the sensor 219 to a comparison current. In other words, the specific configuration of the comparator circuit 225, as well as the inclusion of other circuitry (such as pulse width recognition, or on-time detection circuitry for pulse width modulation (PWM) based sensors 219), can depend on the specific configurations of the sensor (or sensors) 219.

The environmental sense circuitry 220 can include an ADC 228. The ADC 228 can generate a digital output 230 based on the comparator output signal 229 of the comparator circuit 225. The ADC 228 can be configured to generate a digital signal (e.g., 0 or 1) and/or a coded output (e.g., 0001, 0010, etc.) based on the comparator output signal 229. For example, a zero can be generated if the comparison signal 226 at (−) is less than a signal at (+) of the comparator circuit 225. In some examples, the ADC 228 can generate a zero if a sensor 219 generated signal 223 is less than or equal to the comparison signal 226. In other examples, the ADC 228 can generate a zero if a sensor 219 generated signal 223 signal is greater than or equal to the comparison signal 226. In other examples, the ADC 228 can generate a 1 if a sensor 219 generated signal 223 is greater than or equal to the comparison signal 226. In other examples, the ADC 228 can generate a 1 if a sensor 219 generated signal 223 is less than or equal to the comparison signal 226. Referring again to the comparison signal generation circuitry 227 and comparison signal 226, the voltage levels of the comparison signal 226 can depend on the number of bits of the ADC 228. In some embodiments, the levels of the comparison signal 226 can depend on the ADC 228 output 230 and/or the comparator output signal 229.

As previously alluded to, aspects of the present disclosure allow for testing one or more elements of the memory die 104 based on environmental parameters. As such, the environmental sense circuitry 220 can include a sensor emulator 231. The sensor emulator 231 can be configured to generate one or more emulated signals 232 that emulate one or more signals (e.g., the generated signal 223) that can be generated from a sensor (e.g., the sensor 219). In other words, the emulated signal 232 can simulate the sensor 219 generated sensor signal 223, without the sensor 219 having to detect one or more levels of environmental parameter(s) to generate the generated signal 223 with a specific level (e.g., voltage level). For example, the emulated signal 232 can emulate the voltage level that the sensor 219 would generate as the generated signal 223 corresponding to a specific level of an environmental parameter. The sensor emulator 231 can be powered by power signal 207 and enabled by the test enable signal 214, introduced above. The emulated signal 232 can be or be based on the emulation signal 213, which can be generated by one or more controllers (for example, the environmental sensing controller 206 of FIG. 2A, or other controller of memory system 100). Various similar signals were discussed with reference to FIG. 2A and can similarly control the sensor emulator 231. It can be understood that the emulated signal 232 can be configured to generate the ADC 228 output 230, similar to how the ADC 228 can generate the output 230 based on the sensor 219 generated signal 223.

FIG. 2C is a block diagram of an example sensor 257 based environmental sense circuitry 258, which may be representative of the environmental sense circuitry 158, 200, 220 of FIG. 1B, FIG. 2A, FIG. 2B, respectively. Compared to FIG. 1B, FIG. 2A, and FIG. 2B, FIG. 2C shows an alternative configuration of the environmental sense circuitry 158, 200, and 220, including details of the other circuitry 202 shown in FIG. 2A. Like sensor 201 of FIG. 2A and sensor 219 of FIG. 2B, environmental sense circuitry 258 can include sensor 257, which can generate a signal 259 based on one or more sensed environmental parameters. Environmental sense circuitry 258 can include a comparator circuit 260 configured to generate a comparator output signal 263 based on the sensor 257 generated signal 259. A signal at the (−) input of the comparator circuit 260 can be compared to a signal at the (+) input of the comparator circuit 260. For example, the sensor 257 generated signal 259 at the (+) input can be compared with a comparison signal 261 (e.g., to identify if one is less than, equal to, or greater than the other). Based on the comparison, the comparator output signal 263 can be generated by the comparator circuit 260. The comparator output signal 263 can be provided to a control circuit 262.

The control circuit 262 can be an aspect of, or include, an environmental sensing controller 206. Although the control circuit 262 is shown interfacing with the comparator circuit 260, it can be understood that the comparator circuit 260 is part of the control circuit 262. It can also be understood that the control circuit 262 can be a hardware and/or software based module, including as discussed with reference to the environmental sensing controller 206 of FIG. 2A.

Referring to the comparator circuit 260, it is understood that the type of comparator circuit 260 is merely a non-limiting example. For example, if the sensor 257 is configured to generate varying current levels, a CMOS comparator circuit 260 can be used for comparing a current from the sensor 257 to a comparable current based on a SAR output 270. In other words, the specific configuration of the comparator circuit 260, as well as the inclusion of other circuitry (such as pulse width recognition, or on-time detection circuitry for PWM based sensors 257), can depend on the specific configurations of sensors 257.

The environmental sense circuitry 258 can include a successive approximation analog to digital converter (ADC). For example, the environmental sense circuitry 258 can include successive approximation register (SAR) 264. The SAR 264 can be an example ADC 228 (shown in FIG. 2B). The SAR 264 can be configured to generate a digital signal (e.g., 0 or 1), and/or coded output (e.g., 0001, 0010, etc.) based on the comparator output signal 263. For example, the SAR 264 generates a zero if a signal at (−) is less than a signal at (+) of the comparator circuit 260. In some examples, the SAR 264 generates a zero if a sensor 257 generated signal 259 is less than or equal to the comparison signal 261. In other examples, the SAR 264 generates a zero if a sensor 257 generated signal 259 is greater than or equal to the comparison signal 261. In other examples, the SAR 264 generates a 1 if a sensor 257 generated signal 259 is greater than or equal to the comparison signal 261. In other examples, the SAR 264 generates a 1 if a sensor 257 generated signal 259 is less than or equal to the comparison signal 261.

As previously alluded to, aspects of the present disclosure allow for testing one or more elements of the memory die 104 based on environmental parameters. As such, the environmental sense circuitry 258 can include a sensor emulator 268. The sensor emulator 268 can be configured to generate one or more emulated signals 269 that emulate one or more signals that can be generated from a sensor (e.g., the sensor 257 generated signal 259). In other words, the emulated signal 269 can simulate the signal from sensor 257, without the sensor 257 having to detect one or more levels of environmental parameter(s) to generate a signal with a specific level (e.g., voltage level). For example, the emulated signal 269 can emulate the voltage level that the sensor 257 would generate as a sensor signal 259 for a specific level of an environmental parameter. The sensor emulator 268 can be powered by the power signal 207 and enabled by the test enable signal 214. The emulated signal 269 can be based on emulation signal 213, which can be generated by one or more controller (see controller 206 of FIG. 2A, control circuit 262 or other controller of memory system 100). Various similar signals discussed with reference to FIG. 2A can similarly the control sensor emulator 268.

FIG. 2D is a block diagram of an example voltage proportional signal generator 277 based temperature sense circuitry 278, which may be representative of one or more of the environmental sense circuitry 158 of FIG. 1B, the environmental sense circuit 200 of FIG. 2A, or the environmental sense circuitry 258 of FIG. 2C. Like the sensor 201 of the environmental sense circuitry 200 the sensor 257 of the environmental sense circuitry 258, temperature sense circuitry 278 can include a temperature sensor, such as the voltage proportional signal generator 277 that generates a voltage proportional signal 279. Although the voltage proportional signal 279 is shown, this is a non-limiting example, and it can be understood that the temperature sensor can be any environmental sensor. In some embodiments, the voltage proportional signal generator 277 is a band gap reference type of circuit that can provide an output with a voltage proportional to the measured environmental characteristic. The voltage proportional signal generator 277 can generate the voltage proportional signal 279 based on one or more sensed temperatures. For example, the sensed temperature can be the temperature of the memory system 100 or the memory die 104 (see FIG. 1A and FIG. 1B), or portion thereof. The temperature sense circuitry 278 can include a comparator circuit 280 configured to generate a comparator output signal 283 based on the voltage proportional signal 279. The comparator circuit 280 can also include one or more other functionalities, such as amplification. It can also be understood that other circuitry can be included between the comparator circuit 280 and the voltage proportional signal generator 277, such as filtering circuitry, switching circuitry (see the switching circuit 212 with reference to FIG. 2A), and so forth. As such, it can be understood that a switch can be provided between the voltage proportional signal generator 277 and the comparator circuit 280, so the voltage proportional signal generator 277 can be utilized. Further, other filtering and/or amplifying circuitry can be provided.

The voltage proportional signal 279 can be compared with a comparison signal 281 (e.g., if one is less than, equal to, or greater than the other). Based on the comparison, the comparator output signal 283 can be generated. The comparator output signal 283 can be provided to a control circuit 282. Although the control circuit 282 is shown interfacing with the comparator circuit 280, it can be understood that the comparator circuit 280 is part of the control circuit 282. It can also be understood that the control circuit 282 can be a hardware and/or software based module, including the environmental sensing controller 206 shown with reference to FIG. 2A.

The temperature sense circuitry 278 can include a successive approximation analog to digital converter (ADC), including a successive approximation register (SAR) 284. The SAR 284 can be configured to generate a digital (e.g., 0 or 1), based on the comparator output signal 283. In embodiments, successive (e.g., in time) outputs 290 of the SAR 284 can be configured to together create a binary or other coded signal output. The SAR output 290, can be a coded signal based on the value of the environmental parameter. The SAR output 290 can be or be similar to output 204 shown in the circuit 200 of FIG. 2A.

For example, the SAR 284 generates a zero if the voltage proportional signal 279 is less than or equal to the comparison signal 281 (as determined by the comparator circuit 280). In other examples, the SAR 284 generates a zero if the voltage proportional signal 279 is greater than or equal to the comparison signal 281. In other examples, the SAR 284 generates a 1 if the voltage proportional signal 279 is greater than or equal to the comparison signal 281. In other examples, the SAR 284 generates a 1 if the voltage proportional signal 279 is less than or equal to comparison signal 281. In some embodiments, the comparison signal 281 into the comparator circuit 280 is generated by a digital to analog converter (DAC) 286. The DAC 286 can be configured, based on the SAR output 290 (i.e., at a specific time point, i.e., the zero or one) to generate an analog voltage signal output 291 (which can be the comparison signal 281) based on the SAR output 290 (e.g., the prior or current SAR output 290). The DAC 286 can generate the analog signal, further based on a reference voltage 292. The reference voltage 292 can be a temperature-independent reference voltage and can be generated by the environmental sensing controller 206, a voltage source (e.g., of the power control circuitry 156), Zener diode, voltage divider, potentiometer, diode source, or other source. For example, if the SAR output 290 is a zero, the DAC 286 generates a signal that is ½ reference voltage 292. For example, if the SAR output 290 is a zero, the DAC 286 generates a signal that is ½ the prior DAC output 291. In some examples, if the SAR output 290 is a one, the DAC 286 can generate a signal that is double the prior DAC output 291.

In embodiments, in successive timesteps, the comparator circuit 280, the SAR 284, and/or the DAC 286 can together work towards generating a coded SAR output 290. In some examples, a binary search can be performed. A binary search can allow for converging to and/or encoding a value of the voltage proportional signal 279. In embodiments, a successive approximation search can be performed so that a coded SAR output 290 is generated based on the voltage proportional signal 279. For example, the most significant bit (MSB) of the coded SAR output 290 can be based on the first output of the SAR 284. For example, the least significant bit (LSB) of the coded SAR output 290 can be based on the last output of the SAR 284. In examples, the number of bits of the coded output 290 can be based on the bits of the SAR 284. For example, a four-bit SAR 284 can generate sixteen bit coded SAR outputs 290. The coded SAR output 290 can be configured to correspond to various levels for the environmental parameters and/or voltage proportional signal 279.

In embodiments, if the (+) signal into the comparator circuit 280 (e.g., the voltage proportional signal 279) is less than the DAC output 291, the SAR 284 generates a zero. If the (+) signal into the comparator circuit 280, (e.g., the voltage proportional signal 279) is greater than the DAC output 291, the SAR 284 generates a zero. Based on the SAR signal, DAC 286 generates the output 291. As such, the level of the DAC output 291 can continuously change based on subsequent SAR 284 outputs, which can correspond to subsequent bits (e.g., from the MSB to the LSB) of the coded SAR output 290.

The DAC 286 can be configured to generate an output 291 signal that starts as reference voltage 292 (i.e., the voltage level thereof), zero, or 2 reference voltage 292. The DAC 286 can be configured to generate subsequent output(s) 291 (i.e., subsequent to outputs 291 that generated an MSB of a coded output 290 of the SAR 284) that are based on the prior DAC output 291 (for example, results of addition, subtraction, multiplication, etc., operations relative to the prior DAC output 291). For example, the new DAC output 291 can be double of, half of, or an addition or subtraction of half of, the prior DAC 286 output 291. In embodiments, the changed output 291 can allow for searching and/or converging to a coded SAR output 290 that corresponds to the voltage proportional signal 279.

As specific examples, initially the DAC 286 can generate an output 291 that is ½ the reference voltage 292. At the comparator 280, the voltage proportional signal 279 can be compared to the DAC 286 output 291, which is initially ½ the reference voltage 292. Based on the comparator output signal 283, a SAR 284 output signal 290 can be generated, which can be a value for a digit of a coded output. For example, if the voltage proportional signal 279 is less than 291 (which was initially ½ the reference voltage 292) a zero can be generated by the SAR 284 as a bit of the coded SAR output 290. Otherwise (i.e., if the voltage proportional signal 279 is not less than 291) a one can be generated as a bit of (i.e., the LSB of) the coded SAR output 290.

As previously discussed, based on the SAR output 290, the DAC 286 output 291 can be generated. Further, based on the SAR output 290 and the prior DAC 286 output 291 the DAC 286 output 291 can be generated. In other words, 291 can be based on the SAR output 290 and the prior output 291. In examples, if the SAR 284 output is zero, the DAC 286 can generate output 291 that is ½ the prior DAC 286 output 291. If the SAR 284 output is one, the DAC 286 can generate output 291 that is double the prior DAC 286 output 291. If the SAR 284 output (i.e., a specific bit thereof) is a one, a new DAC output 291 can be 2 the prior DAC output 291 plus the prior DAC output 291. In other words, if the SAR 284 output (i.e., a specific bit thereof) is a one, the corresponding DAC output 291 can increase by 2 the prior DAC output 291.

As previously alluded to, aspects of the present disclosure allow for testing one or more elements of the memory die 104 based on environmental parameters. As such, similar to sensor emulator 205 shown in FIG. 2A, and sensor emulator 268 shown in FIG. 2C, temperature sense circuitry 278 can include a voltage proportional signal emulator 298. The emulator 298 can be coupled to the comparator 280, including selectively coupled. It can be understood that other circuitry can be included between the comparator 280 and the emulator 298 (or be part of the emulator 298 and/or comparator 280), such as filtering circuitry, switching circuitry (see switching circuit 212) with reference to FIG. 2A. An example emulation signal 293 discussed with reference to emulation signal 213 in FIG. 2A and FIG. 2C, is an input to the emulator 298. The emulator 298 (and/or switching circuit thereof) can be enabled by one or more signals such as the test enable signal 214, the power signal 207, and/or the emulation signal 293.

The emulator 298 can be configured to generate one or more emulated signals 299 that emulate one or more signals that can be generated from a sensor (e.g., the voltage proportional signal 279). The emulation signal 293 can be varied, for example by controller 206 or other controller or circuit, so that one or more elements of the MD 104 can be tested. In some embodiments, the emulator 298 can generate emulated signal(s) 299 to test aspects of comparator 280, control circuit 282, SAR 284 and/or DAC 286. Similar to testing of other circuits 202 with reference to FIG. 2A by sensor emulator 205, the emulator 298 can be used to test one or more of comparator 280, control circuit 282, SAR 284, and/or DAC 286. The emulated signal 299 can be based on the emulation signal 293. In some embodiments, the emulated signal 299 can simulate the signal from the voltage proportional signal generator 277, without the voltage proportional signal generator 277 having to detect one or more levels of environmental parameter(s) to generate a signal with a specific level (e.g., voltage level). For example, the emulation signal 299 can emulate the voltage level of the voltage proportional signal 279 that voltage proportional signal generator 277 would generate for a specific level of an environmental parameter sensed by an environmental sensor. In some embodiments, comparator 280, control circuit 282, SAR 284, and/or DAC 286 can operate when receiving emulation signal 299 as if when receiving the voltage proportional signal 279. It can be understood that bits of the coded output 290 generated by SAR 284 can be the same for sensor signals 279 and corresponding sensor emulated signal(s) 299 of the same level. For example, binary searching and/or converging to voltage proportional signal 279, can be similarly operated by comparator 280, SAR 284, and/or DAC 286 for binary searching of and/or converging to emulated signal 299.

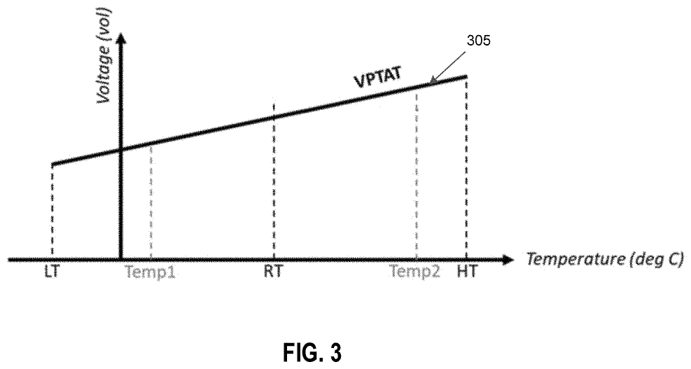

FIG. 3 shows an example voltage level signal 305 from a voltage proportional signal generator. For example, the depicted voltage level 305 can be a temperature signal from voltage proportional signal generator 277 (FIG. 2D). In embodiments, during conventional testing, the environmental temperature can be varied (e.g., at or between a low temperature LT, and at a high temperature HT). However, varying the temperature, can be a long process. For example, it may take time for the local and/or ambient temperature to reach and maintain for testing, the specific temperature LT and/or HT. It may take even longer for the local and/or ambient temperature to reach, and maintain for testing, multiple specific temperatures for testing of the various temperature sense circuitry 278 elements.

The example embodiment of FIG. 3 is based on the temperature dependent voltage proportional voltage level 305 being linear in temperature (or at least a “linear-type” behavior, in that higher order behavior can be neglected and the voltage is sufficiently linear). Example embodiments can use a band gap reference type of circuit providing an output with a voltage proportional to absolute temperature behavior, but other arrangements can be used. For example, an inverse proportional to absolute temperature behavior can be used. In either case, circuits with temperature dependent outputs, such as other band gap based circuits can be used; and although a linear-type temperature dependence is most easily implemented for most other applications, other temperature dependences can also be used.

As previously alluded to, to conventionally test aspects of the temperature sense circuitry (see environmental sense circuits 200, 220, 258, and temperature sense circuitry 278), the environmental temperature was varied (e.g., by varying a temperature in an oven to specific set points). The present disclosure allows for similarly testing elements of memory die 104, at faster speeds, lower cost, and with even further test points (i.e., with finer granularity than conventional testing). The present disclosure also allows for on-the-fly testing, e.g., in the field (i.e., without needing to test in specific environments).

As discussed with reference to FIG. 2A-2D (see, e.g., the emulator 298), the present disclosure allows for generating an emulated temperature analogue for voltage levels (i.e., a voltage proportional signal) and testing aspects of the memory system 100 based on the emulated temperature analogue. In some examples, generating an emulated analogue for voltage proportional signals can include generating an analogue to voltage level 305. Generation of analogues to voltage level 305 without varying one or more environmental parameters can allow for more efficient testing of the memory systems 100. Further, generation of analogues to voltage level 305 without varying one or more environmental parameters, allows for testing of the memory systems 100 at more than merely high HT and low LT temperatures. Testing operations can include generating 4, 5, 10, 20, 25, 30, 50, 75, and so forth, voltage levels (i.e., at or between a low temperature LT and high temperature HT). For example, the emulators described herein (e.g., the emulator 298 in FIG. 2D) can generate voltage levels corresponding to the voltage level of a voltage proportional signal generator (e.g., the generator 277 in FIG. 2D) at low temperature LT, even higher low temperature Temp1, mid-range temperature RT, even lower high temperature Temp2, and high temperature HT.

FIG. 4 shows example control signals generated for voltage proportional signal based sense circuits described herein, and respective coded outputs, in accordance with various embodiments of the present disclosure. FIG. 4 is discussed herein in conjunction with aspects of the temperature sense circuitry 278 of FIG. 2D. However, it can be understood that various signals and coded outputs shown in FIG. 4 can apply to other environmental sense circuits (e.g., the environmental sense circuit 200, 258).

As discussed above, a test enable signal 214 can be generated by the environmental sensing controller 206, or another controller or circuitry. When active (e.g., at a high level) the test enable signal 214 can signify that the temperature sense circuitry 278 is being tested or that a test mode is active. The test enable signal 214 can be configured to activate one or more aspects of the sensor emulator 205, including generation of one or more emulated signals 209. FIG. 4 shows an example test enable signal 405, which may correspond to the test enable signal 214 described above. The test enable signal 405 is active (high) for performance of multiple (e.g., four) tests at various emulated voltage levels. It can be understood that various tests can be performed (i.e., sequentially) and that tests are not limited to the specific voltage levels shown in FIG. 4.

An example emulated signal (shown with reference to FIG. 2A-2D) is shown as emulated signal 410, which may correspond to the emulated signals 209, 232, 269, 299, respectively, described above. Four levels of the emulated signal 410 are shown, for four example tests. In this example, there is a 2-bit bus BUS<1:0> (for example, corresponding to emulation signals 213, 293, referenced in FIGS. 2A-2D) that can set the value of the emulated signal 410 by changing the bus value from which the emulated signal 410 is based automatically. The emulated signal 410 voltage level can be varied accordingly. With reference to FIG. 2D and temperature sense circuit 278, emulated signal 410 can be the emulated signal 299 generated by the emulator 298. In the example of FIG. 2D, the temperature sense circuit 278 can be configured so that emulated signal 410 is coupled to the (+) side of the comparator circuit 280. In the series of tests shown in FIG. 4, emulated signal 410 is varied at stepwise increasing voltage levels but turned off between the four tests when test enable signal 405 is low.

As previously discussed relative to FIG. 2D, the SAR output 290 can be generated based on the emulated signal 299, and further based on at least one comparison between the emulated signal 299 and a signal 291 generated by the DAC 286. Further, the signal 291 can be generated by the DAC 286, based on the SAR output 290. FIG. 4 shows various DAC output signals 412a, 412b, 412c, 412d (for example, corresponding to the DAC output signals 291 described above) for the four tests shown in FIG. 4. The DAC output signals 412a, 412b, 412c, 412d can be based on a temperature-independent reference voltage 413, which may correspond to the reference voltage 292 described above. With reference to FIG. 2D, the DAC output signals 412a, 412b, 412c, 412d can be signals generated by DAC 286, for comparison at the comparator circuit 280.

Also shown are four coded SAR outputs 415, one for each of the corresponding tests (i.e., when the test enable signal 405 is high). The coded SAR outputs 415 shown are four-bit coded outputs, from the MSB (bit 3) to the LSB (bit 0). As previously alluded to with reference to SAR 284, it can be understood that coded SAR output 415 can be of any length, for example, depending on the desired resolution. With reference to FIG. 4, each bit of the coded SAR output 415, can correspond to a respective SAR output 290.

Memory systems 100 can be configured to recognize and work with one or more temperature codes. Thus, it can also be understood that various other codes can be generated. Also shown in FIG. 4, is the outgoing temperature code 414, which can be based on the SAR output 415. A lookup table can be maintained in memory (for example, of the environmental sensing controller 206 or circuit 154 shown in FIG. 1B and FIG. 1A) with the various temperature code 414 values and SAR output 415 values. The temperature code 414 is merely a non-limiting example of possible coded temperature outputs for various memory systems 100. In the tests depicted in FIG. 4, there are four different voltage proportional emulation voltages, for which the final temperature code output temperature code 414 will be ′b0010, ′b0011, ′b0100, and ′b0110, respectively.

At least one of comparator circuit (see, for example, the comparator circuit 280 of FIG. 2D), SAR ADC (see SAR 284 in FIG. 2D, for example), and DAC circuit (see DAC 286 in FIG. 2D, for example) can allow for generation of a zero as a bit of the SAR output 415, and decrease of the DAC output signal 412a, 412b, 412c, 412d if the DAC signal output, 412a, 412b, 412c, 412d is greater than the emulated signal 410. In the example of FIG. 4, DAC output signal 412a, 412b, 412c, 412d is decreased by ½ the prior DAC output signal 412a, 412b, 412c, 412d level. Otherwise, or if the DAC output signal 412a, 412b, 412c, 412d is less than the emulated signal 410 voltage level, a bit of the SAR output 415 can be one and the DAC output signal 412a, 412b, 412c, 412d signal level can increase. In this example, the DAC output signal level can increase by 2 the prior DAC output signal 412a, 412b, 412c, 412d level, respectively.

In a first test shown in FIG. 4, based on a first voltage value for the emulated signal 410 of about 11/64 reference voltage 413, and a DAC output signal 412a in a first test initialized to ½ reference voltage 413, an MSB bit (bit 3) of SAR output 415 can be zero and DAC output signal 412a can decrease to ½ reference voltage 413. Based on that new DAC output signal 412a level as compared to the first value for the emulated signal 410 voltage, the next bit (bit 2) of the SAR output 415 can be set to 0, and the DAC output signal 412a level can further decrease to ⅛ reference voltage 413. Based on a new comparison of the first value of emulated signal 410, with the DAC output signal 412a level of ⅛ reference voltage 413, the next (bit 1) of the SAR output 415 can be set to 1, and the DAC output signal 412a can increase to 3/16 reference voltage 413 (an addition of 1/16 reference voltage 413). Based on a subsequent comparison of DAC output signal 412a and the emulated signal, a zero can be generated for the LSB (bit zero) of the SAR output 415. Based on a coded SAR output 415 (or sequential SAR output 415) of 0010, temperature code 414 ′b0010 can be generated. The generated temperature code 414 during the test can be compared with a predicted or expected temperature code 414 (e.g., in memory of controller 206) and the test can be marked a pass or fail, signifying a functioning or faulty memory die 104, respectively. In embodiments, the memory die 104 can be marked as functioning or faulty, only if one or more of the various tests performed (see four example tests in FIG. 4) fail.

In a second test, emulated signal 410 can be set to 15/64 reference voltage 413, for example, and be compared at various time points to DAC signal output 412b. Like the first test, the output of the comparison can determine the SAR output 415 and/or an increase or decrease of the DAC output signal 412b. The MSB (bit three) of SAR output 415 can be zero, with a decrease of DAC output signal 412b to ¼ reference voltage 413. Based on a subsequent comparison, the next bit (bit two) of the SAR output 415 can be set to zero, with yet another decrease of DAC output signal 412b to ⅛ reference voltage 413. Based on a subsequent comparison, the next bit (bit one) of the SAR output 415 can be one, with an increase of DAC output signal 412b to 3/16 reference voltage 413 (an increase of 1/16 reference voltage 413). Based on a subsequent comparison of DAC output signal 412b with the emulated signal 410, the LSB (bit zero) of SAR output 415 can be set to 1. As the bit depth of the SAR output 415 is four, the temperature code 414 can be generated based on the SAR output 415 of 0011. The second test can be marked a pass or fail, signifying a functioning or faulty memory die 104.

Like the first and second test, in the third test, DAC output signal 412c can be set initially to ½ reference voltage 413, for a comparison to the emulated signal 410, which is set to 9/32 reference voltage 413. The initial comparison can allow for a zero to be set as the MSB (bit three in a four bit SAR ADC) as the SAR output 415, and a decrease of the DAC output signal 412c to ¼ reference voltage 413. The subsequent comparison can allow for setting the next bit (bit two) as a 1 and increasing the DAC output signal 412c by ⅛ to ⅜ the DAC output signal 412c. Based on the comparison of DAC output signal 412c of ⅜ DAC output signal 412c and the emulated signal 410, the next bit (bit one) can be set to 0 and the DAC output signal 412c can decrease by 1/16 to 5/16 reference voltage 413. Based on the next comparison of DAC signal 412c with the emulated signal 410, the LSB SAR output 415 bit (bit zero) can be set to 0, for a four bit SAR output 415 of 0100 and corresponding temperature code 414 out of ′b0100.

In a fourth test, the DAC signal 412d can be set initially to ½ reference voltage 413 and emulated signal 410 set to 13/32 reference voltage 413. Based on series of comparisons of the DAC output signal 412d with the emulated signal 410, the DAC signal output 412d can appropriately adjust (from ½ reference voltage 413 by a decrease of ¼ reference voltage 413 to ¼ reference voltage 413, followed by an increase of ⅛ reference voltage 413 to ⅜ reference voltage 413, and followed by an increase of 1/16 reference voltage 413 to 7/16 reference voltage 413) and the four bit SAR output can be 0110 with temperature code 414 out ′b110.

In various tests of memory die 104, the temperature output value (e.g., at the temperature code 414 out and/or the SAR output 415) can be recorded after adjusting the on-chip voltage source that can generate the emulated signal 410. The memory die 104 can be judged to pass or fail the test, based on a comparison of one or more expected outputs for the respective emulated signal 410, to the actual output (i.e., actual SAR output 415 or temperature code 414 out) during the test. The memory die 104 can pass or fail the test according to the comparison.

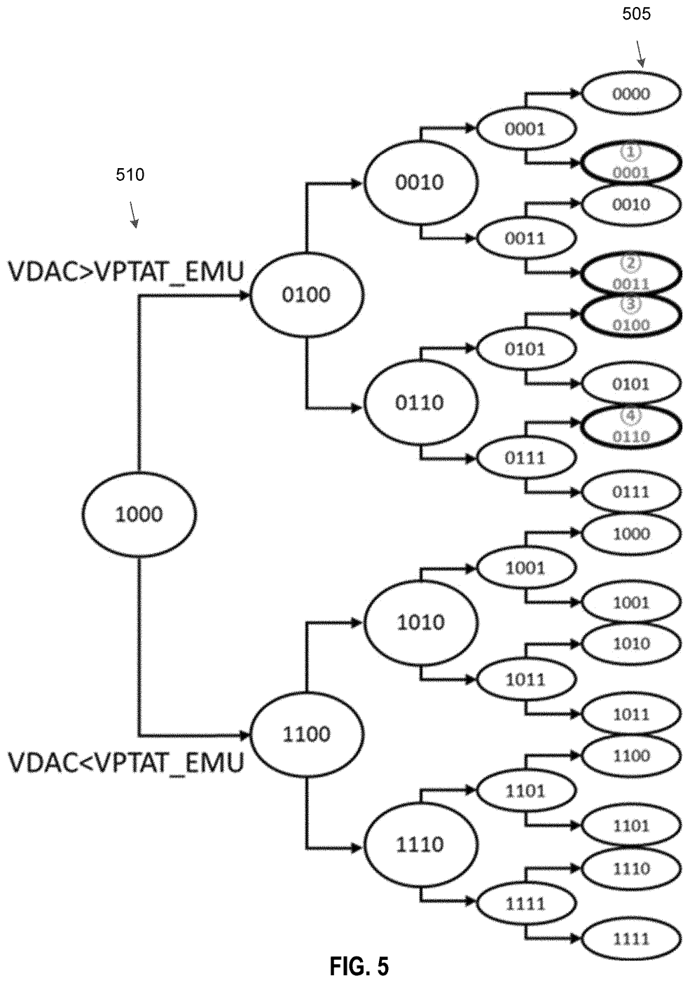

It can be understood that the number of bits of the ADC or SAR (see SAR 284), can determine the resolution of the SAR output 415, and the resolution of successively converging to a solution for the temperature code 414 out. FIG. 5 shows a list of all sixteen possible combinations 505 for a four-bit successive approximation ADC, or SAR 264 or 284, shown in FIG. 2C and FIG. 2D. The sixteen combinations 505 can result in sixteen unique coded SAR outputs 270 or SAR outputs 290, and sixteen unique temperature codes (see example temperature code 414 out in FIG. 4). Comparing FIG. 5 with FIG. 3, it can be understood that each of the sixteen possible combinations 505, can each correspond to non-overlapping portions or margins of voltage level signal 305, so that one or more voltage levels of the voltage level signal 305 map to one of the sixteen possible combinations 505. It can be understood with more bits of SAR 284, a higher resolution of mapping can be achieved. For example, 32 possible combinations 305 for a five-bit SAR 285 can result in double resolution compared to the four-bit SAR 284, and so forth.

Each level of branching 510 in series of branches can correspond to series of comparisons of a DAC output signal to the emulated signal, with subsequently adjusting a DAC output signal, as in the example of FIG. 4 (see DAC output signals 412 and emulated signal 410). Further, four-bit SAR output paths \textcircled{1}, \textcircled{2}, \textcircled{3} and \textcircled{4} are also included, which can correspond to output paths of the four tests shown in FIG. 4, which generated SAR output 415 0010, 0011, 0100, and 0110 respectively, and temperature code 414 out ′b0010, ′b0011, ′b0100, and ′b0110 respectively.

FIGS. 6A and 6B show various steps that can be performed by the environmental sensing controller 206, the controller 102, the control circuit 262, or the control logic circuitry 154 of the peripheral circuit 152, to execute one or more operations in performance of methods 600, 620 respectively. For example, the environmental sensing controller 206 can fetch, decode, and/or execute one or more instructions, for performing various steps of methods 600, 620. Various instructions (e.g., for performing one or more steps described herein) can be stored in non-transitory storage medium of controller 102, 206, and/or control logic circuitry of peripheral circuit 152, where the term “non-transitory” does not encompass transitory propagating signals. “Non-transitory” as used herein refers to any media that store data and/or instructions that cause a machine to operate in a specific fashion. Such non-transitory media may comprise non-volatile media and/or volatile media. Non-volatile media includes, for example, optical or magnetic disks. Volatile media includes dynamic memory. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same. As described in detail below, machine-readable storage medium of controller 102, control circuit 262, control logic circuitry 154, or controller 206 may be encoded with executable instructions, for example, instructions for executing steps of methods 600, 620. Non-transitory media is distinct from but may be used in conjunction with transmission media. Transmission media participates in transferring information between non-transitory media. For example, transmission media includes coaxial cables, copper wire and fiber optics, including the wires that comprise bus between the controller 102 and a host. Transmission media can also take the form of acoustic or light waves, such as those generated during radio-wave and infra-red data communications.

Operations that make up method 600 can include a step 602 enabling a test mode 602. The enabled test mode can be a test mode for testing at least an element of an environmental parameter sense circuit (e.g., environmental sense circuitry 200, 258, or temperature sense circuitry 278). As described herein, enabling testing of memory die 104 is not limiting to situations where various external environmental parameters can be directly measured (e.g., by sensors) and/or varied. Testing as described herein, can be performed on the fly. Test mode can be enabled, including by enabling (i.e., setting to high) a test enable signal (see the test enable signal 214 of FIG. 2A-2D or 405 in FIG. 4). A test mode can be enabled by setting to low, or otherwise adjusting a normal enable signal. In other words, environmental sense circuits described herein can be configured to toggle between normal sense modes and test modes and one or more signals can be adjusted to toggle between the modes. In some examples, step 602 can include activating one or more switches (see switching circuits 210, 212 in FIG. 2A) coupled between at least one of a sensor and other circuits of the environmental sense circuit, and a sensor emulator of an environmental sense circuit and other circuits of the environmental sense circuit.

Step 604 of method 600 can include generating an emulation signal. Generated emulation signal can be the emulation signal 213 shown in FIG. 2A, FIG. 2B, and FIG. 2C and the emulated signal 293 shown in FIG. 2D and 410 in FIG. 4. Step 606 of method 600 can include testing sensor circuitry based on the emulation signal (e.g., the emulation signal generated at step 604). Step 606 can include testing sensor circuitry, such as other circuitry 202, comparator 260, 280, control circuit 262, 282, SAR 264, 284, and DAC 266, 286. In examples of method 600, the tested sensor circuitry can include other elements of memory device 104. In some examples, testing sensor circuitry can include generating a sense circuit output (see output 204 in FIG. 2A) and/or a SAR output (see SAR output 270, SAR output 290, and SAR output 415). In some examples, testing sensor circuitry in step 606 can include generating a coded output, e.g., the temperature code 414 out in FIG. 4-FIG. 5. In examples, testing sensor circuitry can include comparing the generated sense circuit output, SAR output (which can be a coded output), and/or temp code output to an expected value. For example, testing sensor circuitry in step 606 can include comparing an expected temperature code out to a temperature code out generated during testing (see examples in the bottom of FIG. 4).

Method 620 can include step 622 for enabling a test mode. Test mode can be enabled as described with reference to step 602 of method 600, including enabling a test mode for a temperature sense circuit (see temperature sense circuit 798). Method 620 can include step 624 for generating an emulation signal, such as emulation signal 410. Step 624 can include one performing or more aspects of step 604. Step 624 can include enabling emulator 298 to generate one or more emulated signals 299 (see FIG. 2D). The emulated signal 299 can be emulated signal 410 or based on the emulated signal 410. The emulated signal 410 can be based on the voltage level 305 curve (see FIG. 3). The voltage level 305 curve can be specific to a voltage proportional signal generator 277 of the temperature sense circuit 278 that the emulator 298 is coupled to.

Method 620 can include step 626 for testing temperature sense circuitry based on the emulated signal. Step 626 can include aspects of step 606 of method 600.

Step 626 can include step 628 for generating the emulated signal (for example, if not generated at state 624) and DAC output signal. DAC output signal can be initialized to a value. The initialized value can be based on a reference voltage. The DAC output signal can be generated by DAC 286 with reference to FIG. 2D. The DAC output signal can include DAC output signal 412a, 412b, 412c, 412d shown in FIG. 4.

Step 626 can include step 630 for comparing the DAC output signal (i.e., the signal generated at step 628). Step 630 can be performed by comparator 280 shown with reference to FIG. 2D.

Step 632 can include generating a SAR output. The SAR output can be based on an outcome of the comparison. The SAR output, in embodiments, can be a zero or a one, depending on an outcome of the comparison at step 630. The SAR output can include SAR output 290 as shown in FIG. 2D, and/or SAR output 415 shown in FIG. 4. In embodiments, the SAR output can include a single digit, which, upon one or more recursions, forms a multi-digit coded output. As such, the generated SAR output, at or after step 632 can be part of a multi-digit coded output.

Steps 628, 630, 632 can be performed recursively. As such, at or after step 632, a recursion can be initialized if the bits of a coded output, for example, a multi-digit coded output, have not been fully written, for example by way of the SAR having a bit size. For example, the generated SAR output, at step 632, can be written to an MSB of a coded output of bit length bl. The bit length bl can depend on the bit depth of the SAR. For example, at a first instance of step 628, the DAC output signal and the emulation signal can be initialized. In subsequent recursions of step 628, the DAC output signal can be updated (see for example FIG. 4, where DAC output signal 412a, 412b, 412c, 412d is updated based on an outcome of comparison of DAC output signal 412a, 412b, 412c, 412d, to the emulated signal 410). The DAC output signal can be updated based on at least the prior or current value of DAC output signal, and an outcome of the comparison stat step 630 (i.e., the prior recursion). In embodiments, the value for the DAC output signal can be based on the value of the previously generated SAR output 632.

In some embodiments, with a bitlength bl and number of recursions (i.e., the number of times steps 628-632 are performed), at step 632, the bl-r bit can be updated or written with the generated SAR output of step 632. For example, at the first recursion, bit bl-1 (the MSB) can be updated. At the second recursion, or the second time step 632 is performed, at step 632, bit bl-2 bit can be updated with the SAR output. The number of recursions 633 can depend on the bitlength bl. For example, for a bit length of four, there can be a first recursion and three subsequent recursions 633.

Step 626 can include step 634 for generating one or more coded output. The coded output can have a bit length or bit depth (e.g., one, two, three, four, five, six, etc. bit depth). The bit depth can be the number of bits of a SAR ADC. The number of possible coded outputs can depend on the bit depth (see for example FIG. 5 with sixteen possible codes for a bit depth of four). At the end of the various recursions of steps 628, 630, and/or 632, a coded output can be generated at step 634. The coded output can include coded SAR output 290 shown in FIG. 2D, SAR output 415 shown in FIG. 6. The coded output can also include a temperature code. For example, see various example temperature codes shown in FIG. 4.

When a coded output is generated at step 634, step 628 can be recursively performed for a new emulated signal. At subsequent tests, which can include more than one recursion of steps 628, 630, and 632, the emulated signal can be updated. In embodiments, a test plan can include testing the temperature sense circuit 278 such that values of output of the circuit 278 are generated for at various emulated signal voltage levels.

Based on the value of coded output 634, for one or more tests at various emulated signals, system and methods described herein can allow for determining the health and/or failure state of memory die 104. For example, the coded generated coded output 634, can be compared to an expected coded output, and a failure state can be determined based on the comparison.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example embodiments. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAs, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as memory system 100.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

1. A circuit, comprising:
a sensor circuit configured to generate a first voltage level based on a sensed environmental parameter;
an output circuit configured to generate a coded output based on the first voltage level; and
a voltage generator configured to generate a second voltage level that simulates the first voltage level;
wherein:
the output circuit is configured to generate a first coded output based on the first voltage level in a first mode; and
the output circuit is configured generate a second coded output based on the second voltage level in a second mode.

2. The circuit of claim 1, wherein the voltage generator is embedded in a memory die.

3. The circuit of claim 2, further comprising a memory die controller configured to determine a fault status of the memory die based on the second coded output.

4. The circuit of claim 1, wherein the sensor is a voltage proportional to absolute temperature generator.

5. The circuit of claim 1, wherein the environmental parameter is a temperature, and wherein the voltage generator is configured to generate the second voltage level regardless of a value for the temperature.

6. The circuit of claim 1, wherein in the second mode, the sensor circuit is decoupled from the output circuit and the voltage generator is coupled to the output circuit, and wherein in the first mode, the sensor circuit is coupled to the output circuit.

7. The circuit of claim 1, wherein the output circuit comprises:
a successive approximation register analog to digital converter circuit (SAR), the SAR configured to generate a SAR digital output;
a digital to analog converter (DAC) coupled to the SAR, the DAC configured to generate a third voltage level based on the SAR digital output; and
a comparator circuit configured to generate a comparison of the second voltage level and the third voltage level;
wherein the SAR digital output is based on the comparison by the comparator circuit.

8. The circuit of claim 7, wherein the SAR digital output is a zero if the third voltage level is greater than the second voltage level.

9. The circuit of claim 7, wherein the DAC configured to generate the third voltage level comprises the DAC configured to:
initialize the third voltage level based on a reference voltage, and
update the third voltage level based the SAR digital output generated after the comparison of the second voltage level and the third voltage level that was initialized based on a reference voltage.

10. The circuit of claim 9, wherein:
the third voltage level is initialized to ½ the reference voltage;
if the SAR digital output is of a first level of two possible levels, the third voltage level is increased by ¼ the reference voltage; and
if the SAR digital output is of a second level of two possible levels, the third voltage level is decreased by ¼ the reference voltage.

11. The circuit of claim 9, wherein:
the comparator circuit is further configured to compare the updated third voltage level and the second voltage level; and
the SAR has a bit length of size bl and is configured to:
set a bl-1 bit of the second coded output as the SAR digital output that was generated after the comparison of the second voltage level and the third voltage level that was initialized based on the reference voltage, and
set a bl-2 bit of the second coded output as the SAR digital output that was generated based on the updated third voltage level.

12. The circuit of claim 11, wherein the comparator circuit is further configured to update the third voltage level based on a level of a bl-n bit of the second coded output, where n>1, and wherein the third voltage level is updated by increasing the third voltage level by ½ the prior third voltage level, if the level of the bl-n bit of the second coded output is of a first level of two possible levels, and decreasing the third voltage level by ½ the prior third voltage level if the level of the bl-n bit of the second coded output is of a second level of two possible levels.

13. A controller, comprising:
a processor operative to:
generate a test enable signal, the test enable signal configured to enable a test mode for testing an environmental parameter sense circuit of a memory die;
generate an emulation signal, the emulation signal configured to emulate a voltage level of a sensor, the sensor configured to detect the environmental parameter and generate the voltage level;
receive a coded output, the coded output based, at least in part, on the emulation signal; and
determine a memory die fault status based on the coded output.

14. The controller of claim 13, wherein the coded output is further based on:
a comparison of the emulation signal to a comparison signal;
a digital output generated based on the comparison of the emulation signal to the comparison signal; and
an update of the comparison signal based on the digital output.

15. The controller of claim 14, wherein the coded output is further based on the digital output being a first level of two possible levels in response to the comparison signal being greater than the emulation signal.

16. The controller of claim 14, wherein the coded output is further based on the digital output being a second level of two possible levels in response to the emulation signal being greater than the comparison signal.

17. The controller of claim 14, wherein coded output is further based on:
an initialization of the comparison signal based on a reference voltage; and
an update of the comparison signal based the digital output that was generated based on the comparison of the emulation signal to the initialized comparison signal.

18. The controller of claim 17, wherein coded output is further based on:
an initialization of the comparison signal to ½ the reference voltage; and
an update of the comparison signal based on:
an increase of the comparison signal by ¼ the reference voltage in response to the digital output being of a first level of two possible levels, or
a decrease of the comparison signal by ¼ the reference voltage level in response to the digital output being of a second level of two possible levels.

19. The controller of claim 17, wherein the coded output has size bl, and wherein the coded output is further based on:
a comparison of the updated comparison signal to the emulation signal;
setting a bl-1 bit of the coded output as the digital output that was generated after the comparison of the emulation signal and the initialized comparison signal, and;
setting a bl-2 bit of the coded output based on the comparison of the updated comparison signal with the emulation signal.

20. A method, comprising:
testing a circuit response for a circuit to environmental parameters based on:
generating, in a simulation mode, a simulated voltage simulating a voltage generated by an environmental sensor measuring an aspect of an environment of the circuit being tested;
generating a coded output based on a comparison of the simulated voltage to a comparison signal received from a digital to analog converter; and
determining a fault status of a memory die comprising the circuit based on the coded output,
wherein the simulated voltage is adjustable based on a comparison of the analog signal to simulate environmental changes measured by the environmental sensor.
